(19) United States
(12) Patent Application Publication
(10) Pub. No.: US 2026/0112578 A1
(43) Pub. Date: Apr. 23, 2026

(54) SUBSTRATE PROCESSING APPARATUS

(71) Applicant: Samsung Electronics Co., Ltd., Suwon-si (KR)

(72) Inventors: Hadong JIN, Suwon-si (KR); Taekjin KIM, Suwon-si (KR); Kanghee KIM, Suwon-si (KR); Dongwan KIM, Suwon-si (KR); Hyosin KIM, Suwon-si (KR); Youngjin NOH, Suwon-si (KR)

(21) Appl. No.: 19/185,021

(22) Filed: Apr. 21, 2025

(30) Foreign Application Priority Data
Oct. 18, 2024 (KR) 10-2024-0142662

(51) Int. Cl. H01J 37/32

(52) U.S. Cl. CPC H01J 37/32174; H01J 37/32146; H01J 37/3244; H01J 37/32642; H01J 37/32724; H01J 2237/334

(57) ABSTRACT

A substrate processing apparatus includes a chamber, a substrate support disposed in the chamber and supporting a substrate, a RF power source providing an RF power to the substrate support, an RF power transmission line electrically connecting the substrate support to the RF power source, a driven element disposed in the chamber, a driving source providing a driving signal to the driven element, a connection line electrically connecting the driven element to the driving source, a resonator disposed on the connection line, and a resonance control circuit including a resonator controller that controls a resonance frequency of the resonator. The RF power transmission line and the connection line have different paths.

### CROSS-REFERENCE TO RELATED APPLICATION

This application claims priority under 35 U.S.C. § 119 to Korean Patent Application No. 10-2024-0142662, filed in the Korean Intellectual Property Office on Oct. 18, 2024, the entire contents of which are hereby incorporated by reference.

### BACKGROUND

### Field

The present disclosure is related to a substrate processing apparatus.

### Description of Related Art

In general, a series of processes such as deposition, etching, and cleaning may be performed to manufacture a semiconductor device. Such processes may be performed using a deposition, etching, or cleaning device equipped with a process chamber. As the integration and miniaturization of devices progress, the demand for high-quality metal films with uniform thickness has increased significantly. Accordingly, various methods have been studied to stably form micropatterns and deposit the thin films of high quality.

The above-described information is only to improve the understanding of the background of the present disclosure, but may include information that is not relevant to the conventional technology.

### SUMMARY

The present disclosure is aimed to provide a substrate processing apparatus for solving the above-described problem.

The problem to be solved is not limited the above, but the other tasks not mentioned above may be explicitly known to those skilled in the art from the description of the present disclosure below.

According to embodiments of the present disclosure, a substrate processing apparatus may include a chamber in which a substrate processing process is performed, a substrate support disposed in the chamber and configured to support a substrate, a radio frequency (RF) power source configured to provide an RF power to the substrate support, an RF power transmission line configured to electrically connect the substrate support to the RF power source, a driven element disposed in the substrate support or the shower head, a driving source configured to provide a driving signal to the driven element, a connection line configured to electrically connect the driven element to the driving source, a resonator disposed on the connection line, and a resonance control circuit including a resonator controller that controls a resonance frequency of the resonator. The RF bias transmission line and the connection line have different paths.

According to embodiments of the present disclosure, a substrate processing apparatus may include a chamber in which a substrate processing process is performed, a substrate support disposed in the chamber, and configured to support a substrate, an adsorption electrode disposed in the substrate support, an adsorption electrode power source configured to apply a power to the adsorption electrode, a first connection line configured to electrically connect the adsorption electrode to the adsorption electrode power source, a first resonator disposed on the first connection line, an edge ring in a ring shape disposed on the substrate support, an edge ring control signal source configured to apply an impedance control signal to a region adjacent to the edge ring via a second connection line, a second resonator disposed on the second connection line, and a resonance control circuit configured to control a resonance frequency of at least one of the first resonator and the second resonator.

According to embodiments of the present disclosure, a substrate processing apparatus may include a chamber in which a substrate processing process is performed, a substrate support disposed in the chamber and configured to support a substrate, a shower head disposed in the chamber to face the substrate support, an RF power source configured to provide an RF power to the substrate support, an RF power transmission line configured to electrically connect the substrate support to the RF power source, an adsorption electrode disposed in the substrate support, an adsorption electrode power source configured to apply a power to the adsorption electrode, a first connection line configured to electrically connect the adsorption electrode to the adsorption electrode power source, a first resonator disposed on the first connection line, a heater disposed in the shower head, and configured to discharge heat when a heater power is applied, a heater power source configured to apply the heater power to the heater, a second connection line configured to electrically connect the heater to the heater power source, a second resonator disposed on the second connection line, an edge ring in a ring shape disposed on the substrate support, an edge ring control signal source configured to apply an impedance control signal to a region adjacent to the edge ring via a third connection line, a third resonator disposed on the third connection line, and a resonance control circuit including a resonator controller configured to control a resonance frequency of at least one of the first resonator, the second resonator, and the third resonator, wherein the RF power transmission line, the first connection line, the second connection line, and the third connection line have different paths.

According to embodiments, harmonics in a plasma chamber may be effectively controlled by controlling a resonator for a driven element in a substrate processing apparatus, thereby uniformly performing the etching of a substrate which is the target of a plasma process.

The effect that is obtained from the present disclosure is not limited the above. The technical effect not mentioned above may be explicitly known to those skilled in the art from the description below.

### BRIEF DESCRIPTION OF DRAWINGS

FIG. 1 is a view illustrated to explain a substrate processing apparatus according to embodiments of the present disclosure.

FIG. 2 is a view illustrated to explain a resonator according to embodiments of the present disclosure.

FIG. 3 is a view illustrated to explain a resonator according to another embodiment of the present disclosure.

FIG. 4 is a view illustrated to explain a resonator according to yet another embodiment of the present disclosure.

FIG. 5 is a graph illustrating an etching rate of a substrate in a chamber.

FIG. 6 is a graph illustrating components of a fundamental frequency and a harmonic of a very high frequency among frequencies of an RF power on a transmission line.

FIG. 7 is a graph illustrating a change of a characteristic of an impedance in a chamber in the substrate processing apparatus of FIG. 1.

FIG. 8 is a graph illustrating a change in an etching rate at a center in a chamber of the substrate processing apparatus of FIG. 1.

FIG. 9 is a block diagram illustrating internal components of a resonance control unit according to embodiments of the present disclosure.

FIG. 10 is a view illustrated to explain a substrate processing method according to embodiments of the present disclosure.

FIG. 11 is a view illustrated to explain a substrate processing method according to embodiments of the present disclosure.

FIG. 12 is a view illustrated to explain a substrate processing apparatus according to embodiments of the present disclosure.

FIG. 13 is a view illustrated to explain a substrate processing apparatus according to embodiments of the present disclosure.

FIG. 14 is a view illustrated to explain a substrate processing apparatus according to embodiments of the present disclosure.

FIG. 15 is a view illustrated to explain a substrate processing apparatus according to embodiments of the present disclosure.

Embodiments of the technical spirit of the present disclosure will be described in detail with reference to the attached drawings. Like reference numerals in the drawings denote like elements, and the redundant description will be omitted.

### DETAILED DESCRIPTION

With reference to the attached drawings, an electrostatic chuck and a substrate processing apparatus including the same will be described in detail. Like reference numerals in the drawings denote like elements, and the size of each element in the drawings may be exaggerated for clarity and ease of explanation. The embodiment described below is only exemplary, but it is to be understood that various changes and modifications may be made to embodiments of the present disclosure without departing from the spirit and scope of the invention.

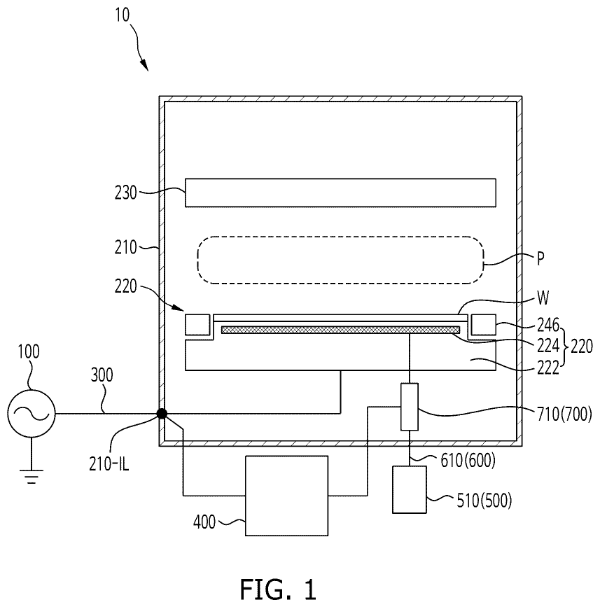

FIG. 1 is a view illustrated to explain a substrate processing apparatus 10 according to embodiments of the present disclosure.

The substrate processing apparatus 10 may generate plasma P. The substrate processing apparatus 10 may include a Capacitively Coupled Plasma (CCP) source, an Inductively Coupled Plasma (ICP) source, a microwave plasma source, or a remote plasma source.

The substrate processing apparatus 10 may be an apparatus that performs the process of processing a substrate W to manufacture a semiconductor device by using the plasma P. For example, the substrate processing apparatus 10 may perform one of plasma annealing, plasma etching, plasma enhanced chemical vapor deposition, sputtering, and plasma cleaning on the substrate W.

The substrate W may be a semiconductor substrate for forming micropatterns for the semiconductor device. For example, the substrate W may be a semiconductor substrate including silicon or germanium. As another example, the substrate W may be a silicon on insulator (SOI) substrate. According to yet another embodiment, the substrate W may be a glass substrate.

Referring to FIG. 1, the substrate processing apparatus 10 according to embodiments may include a Radio Frequency (RF) power source 100, a chamber 210, an electrostatic chuck 220, a shower head 230, an RF bias transmission line 300 (i.e., an RF power transmission line), a resonance control unit 400, a driving source 500, a connection line 600, or a resonator 700.

The RF power source 100 may supply an RF power to the electrostatic chuck 220. For example, the RF power source 100 may generate the RF power having the frequencies of several tens of kHz to several hundred of MHz. The RF power source 100 may generate the RF power having the power level of several hundred watts to several thousand watts. Accordingly, the plasma characteristics suitable for specific process conditions may be adjusted. For example, the RF power of high frequency may generate plasma, and the RF power of low frequency may supply energy to ions. The RF power source 100 may transmit an RF power to the electrostatic chuck 220 through the RF bias transmission line 300.

The frequency range and power of the RF power generated by the RF power source 100 are not limited to the above-described frequency range and power. For example, according to embodiments, the RF power source 100 may generate the RF power having the frequencies of tens of kHz or less or hundreds of MHz or more. The RF power source 100 may generate the RF power having the power level of hundreds of watts or less or thousands of watts or more.

According to the substrate processing apparatus 10 of the embodiments of the present disclosure, the RF power source 100 may be a power supply that supplies a power to the electrostatic chuck 220. The electrostatic chuck 200 may be a load supplied with a power from the RF power source 100.

Although not shown, a matcher for controlling an impedance may be placed between the RF power source 100 and the electrostatic chuck 220. The matcher may control an impedance to satisfy the Complex Conjugate condition based on the maximum power delivery theory, thereby maximizing RF power transmission. The matcher may allow the RF power source 100 to operate in the environment of 50 Ω, minimizing reflected power and ensuring maximum transmission of RF power to the electrostatic chuck 220.

The chamber 210 may provide a space for performing a substrate processing process in a vacuum state. The inside of the chamber 210 may be sealed to control the process environment, and the pressure, temperature, and gas flow inside the chamber may be controlled through a separate control system. The chamber 210 may be made of a durable material to be maintained in a high vacuum state. For example, the chamber 210 may include metals such as aluminum and stainless steel, but the present disclosure is not limited thereto. The chamber 210 may be maintained in a grounded state to block noises from the outside during the plasma process. Although not shown, a gas inlet, a gas outlet, or a view-port may be formed in the chamber 210. A process gas required for the plasma process may be supplied through the gas inlet. The process gas may indicate all gases required for the plasma process such as a source gas, a reaction gas, and a purge gas. After the plasma process, the gases inside the chamber 210 may be exhausted to the outside through the gas outlet. The pressure inside the chamber 210 may be adjusted through the gas outlet. One or more view ports may be formed in the chamber 210, and the inside of the chamber 210 may be monitored through the view ports.

The electrostatic chuck 220 may be placed at the lower portion inside the chamber 210. The substrate W that is the target of the plasma process may be placed and fixed on the upper surface of the electrostatic chuck 220. The electrostatic chuck 220 may fix the substrate W by an electrostatic force. The electrostatic chuck 220 may include a bottom electrode for the plasma process. The electrostatic chuck 220 may be connected to the RF power source 100 through the RF bias transmission line 300. Accordingly, the RF power from the RF power source 100 may be applied to the inside of the chamber 210 through the electrostatic chuck 220. The electrostatic chuck 220 may include a substrate support 222, which is a body of the electrostatic chuck 220. The substrate support 222 may be connected to the RF power source 100 through the RF bias transmission line 300.

The electrostatic chuck 220 may further include an adsorption electrode 224 and an edge ring 246. The substrate support 222 may correspond to the body of the electrostatic chuck 220. The adsorption electrode 224 may be an electrode for applying power for chucking/dechunking of the substrate W. The adsorption electrode 224 may be placed in the substrate support 222. The substrate W, which is the target of the plasma process, may be placed on the upper surface of the substrate support 222 and fixed by the electrostatic force generated by the adsorption electrode 224. The edge ring 246 may have a ring shape. The edge ring 246 may be placed on the substrate support 222 in a structure that surrounds the substrate W. The edge ring 246 may be formed of silicon and serve to expand the silicon area of the substrate W, thereby preventing the plasma P from concentrating at the edge portion of the substrate W. The edge ring 246 may be one of one-ring type and two-ring type. The one-ring type is referred to as a focus ring and the two-ring type is referred to as a combo-ring.

The shower head 230 may be placed in the upper portion inside the chamber 210. The shower head 230 may be placed to face the substrate support 222. The shower head 230 may spray the process gases supplied through the gas inlet into the chamber 210 through a plurality of spray holes. The shower head 230 may include a top electrode. The shower head 230 may be connected to, for example, a ground in the plasma process.

The resonance control unit 400 may control harmonics for a Very High Frequency (VHF) among the frequencies of an RF power by controlling the resonance frequency of the resonator associated with the driven element disposed in the chamber 210. For example, the driven element may be disposed at the substrate support 222 or the shower head 230. Therefore, the plasma distribution in the chamber 210 may be adjusted. The driven element, among various components of the substrate processing apparatus 10, may indicate a component that is driven by an applied driving signal (e.g., a power signal or an impedance control signal) and has an electrical influence on the inside of the chamber 210. The distribution of the plasma may refer to the density distribution of the plasma. In an embodiment, the VHF may refer to as a frequency higher than the commonly used 13.56 MHz in plasma equipment. In an embodiment, the VHF refers to radio frequencies in the range of 30 MHz to 300 MHz. In an embodiment, the RF power source 100 may supply VHF RF power to the electrostatic chuck 220, which may serve as a plasma electrode for generating plasma. The electrostatic chuck 220 may securely hold the wafer while also serving as part of the RF electrode system generating plasma.

A driving source 500 may provide a drive signal to a driven element. According to embodiments, the driving source 500 may be a power source. For example, the driving source 500 may include a direct current (DC) power source or an alternating current (AC) power source. According to another embodiment, the driving source 500 may be a signal source. For example, the driving source 500 may include a driven element control signal source. The driven element may be driven by receiving a driving signal from the driving source 500. In this case, the driving signal may form an electrical field in the chamber or change an impedance to change an electrical characteristic in the chamber 210. For example, such an electrical field generated by the driving signal may be applied to an internal space of the chamber 210 where plasma is generated, affecting the plasma impedance.

A connection line 600 may be disposed between the driven element and the driving source 500. The connection line 600 may be implemented as, for example, a cable, a strap, or a rod, but the present disclosure is not limited thereto. The connection line 600 may be implemented as a conductive path that transmits a driving signal from the driving source 500 to the driven element. The connection line 600 may be implemented as a different path from the RF bias transmission line 300. The connection line 600 may be used to transmit the driving signal from the driving source 500 to the driven element, and the connection line 600 may be disposed separately from a path along which the RF bias transmission line 300 transmits an RF signal.

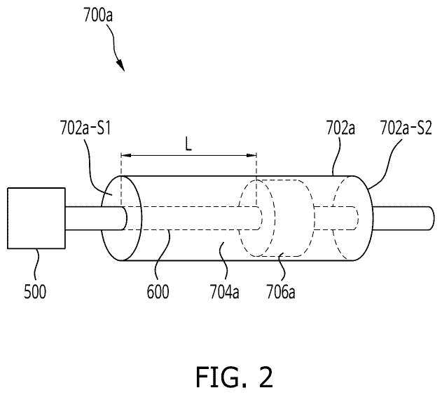

The resonator 700 may be disposed on the connection line 600 between the driven element and the driving source 500. The resonator 700 may include a structure that changes the resonance in a specific frequency band by the resonance control unit 400. The resonator 700 may resonate the electric field generated by the connection line 600 by the resonance control unit 400. For example, the resonator 700 may be implemented as a cavity resonator, a dielectric resonator, or a resonance circuit. However, the present disclosure is not limited thereto. The description of the structure of the resonator 700 will be described in detail below with reference to FIG. 2 to FIG. 4.

According to embodiments, the connection line 600 itself may function as the resonator 700. The connection line 600 may have a structure that changes the resonance in a specific frequency band by the resonance control unit 400. In an embodiment, the connection line 600 with the resonator 700 may have an adjustable resonance frequency.

According to embodiments, the driven element may include an adsorption electrode 224 disposed in the substrate support 222. The driving source 500 may include an adsorption electrode power source 510 that applies a power to the adsorption electrode 224. Referring to FIG. 1, the adsorption electrode power source 510 may be electrically connected to the adsorption electrode 224 through a first connection line 610. A first resonator 710 may be disposed on the first connection line 610. The resonance control unit 400 may control the resonance frequency of the first resonator 710. The resonance control unit 400 may change the resonance in a specific frequency band by controlling the first resonator 710, thereby adjusting the impedance of the chamber 210 in a specific frequency band.

According to embodiments, the first connection line 610 itself may function as the first resonator 710. The first connection line 610 may have a structure that changes the resonance in a specific frequency band by the resonance control unit 400.

FIG. 2 is a view illustrated to explain a resonator 700a according to embodiments of the present disclosure. The resonator 700a may include a casing 702a that surrounds at least part of the connection line 600 by a predetermined distance, and a dielectric 706a that partially fills an internal space 704a between the connection line 600 and the casing 702a and is movable along the longitudinal direction of the casing 702a. In an embodiment, the dielectric 706a may be movably attached to the connection line 600 and the casing 702a. For example, the dielectric 706a may fit into the internal space 704a and may be slidable along the connection line 600.

The casing 702a may provide the internal space 704a to form a cavity. Therefore, an electromagnetic wave by the driving signal transmitted through the connection line 600 may be resonated. The casing 702a may be formed in a cylindrical or hexahedral shape. However, the shape of the casing 702a of the present disclosure is not limited thereto. The casing 702a may include a conductive material. For example, the casing 702a may include metal materials such as aluminum, copper, and stainless steel.

The dielectric 706a may move inside the casing 702a. As the dielectric 706a moves inside the casing 702a, an electrical length L of the resonator 700a may be adjusted. The resonance frequency may change according to the movement of the dielectric 706a. In an embodiment, the casing 702a may have opposite first and second end surfaces 702a-S1 and 706a-S2, and the dielectric 706a may be disposed in a space between the first end surface 706a-S1 and the second end surface 706a-S2. The first end surface 706a-S1 may be closer to the driving source 500 than the second end surface 706a-S2. The electrical length L may correspond to a distance between the first end surface 706a-S1 and the dielectric 706a. The casing 702a may further include a side surface connecting the first end surface 706a-S1 to the second end surface 706a-S2. The connection line 600 may penetrate through the first and second end surfaces 706a-S1 and 706a-S2.

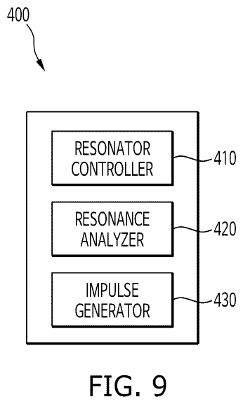

According to embodiments, the resonance control unit 400 may include a resonator controller (e.g., 410 of FIG. 9). The resonator controller may control a resonance frequency of the resonator 700a by adjusting the position of the dielectric 706a. For example, the resonator controller may control the resonance frequency of the resonator 700a by adjusting the electrical length L of the resonator 700a by controlling the position of the dielectric 706a. As the position of the dielectric 706a changes, the electrical length L for the resonance of the resonator 700a may change. Accordingly, the resonance frequency of the resonator 700a may change.

Therefore, according to the change of the impedance characteristic inside the chamber (e.g., 210 of FIG. 1), the harmonics for the very high frequency among the frequencies of the RF power may be controlled.

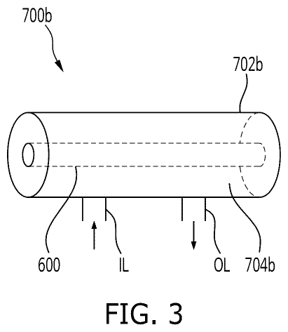

FIG. 3 is a view illustrated to explain a resonator 700b according to another embodiment. According to embodiments, the resonator 700b may include a casing 702b that surrounds at least part of the connection line 600 by a predetermined distance, a dielectric that fills an internal space 704b between the connection line 600 and the casing 702b.

The casing 702b may provide the internal space 704b to form a cavity. Accordingly, the electromagnetic wave by the driving signal transmitted through the connection line 600 may resonate. The casing 702b may be formed in a cylindrical or hexahedral shape. However, the shape of the casing 702b of the present disclosure is not limited thereto. The casing 702b may include a conductive material. For example, the casing 702b may include metal materials such as aluminum, copper, and stainless steel.

The internal space 704b of the casing 702b may be filled with a dielectric. According to embodiments, the casing 702b may include an inlet IL through which the dielectric flows in and an outlet OL through which the dielectric flows out. As the dielectric flows in or out of the casing 702b, the electrical characteristics of the resonator 700b may be adjusted. Accordingly, the resonance frequency of the resonator 700b may change.

According to embodiments, the resonator controller (e.g., 410 of FIG. 9) may control the resonance frequency of the resonator 700b by adjusting the inflow and outflow of the dielectric. For example, the resonator controller may adjust the density of the dielectric by the inflow or outflow of the dielectric inside the casing 702b. The resonator controller may control the resonance frequency of the resonator 700b by adjusting the electrical characteristic of the resonator 700b. As the density of the dielectric changes, the electrical characteristic for the resonance of the resonator 700b may change, thereby changing the resonance frequency.

Accordingly, the impedance characteristic inside the chamber (210 of FIG. 1) may be changed to control the harmonics for the very high frequency among the frequencies of the RF power.

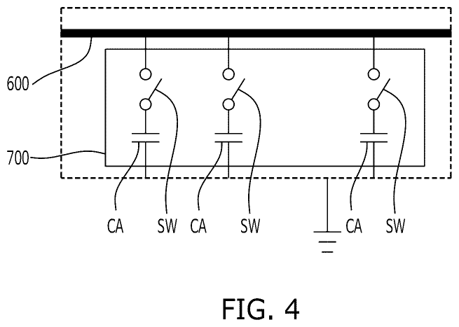

FIG. 4 is a view illustrated to explain a resonator 700c according to yet another embodiment of the present disclosure. According to embodiments, the resonator 700c may include a plurality of capacitors CA connected in parallel on a connection line 600, and a plurality of switches SW disposed with the respective capacitors CA on the connection line 600.

According to embodiments, the resonator controller (e.g., 410 of FIG. 9) may control the resonance frequency of the resonator 700c by controlling the operations of the plurality of switches SW. For example, the total capacitance of the capacitors CA may be adjusted according to the selective opening and closing operation of the switches SW, so that the electrical length and the resonance frequency of the resonator 700c may change. In an embodiment, an electrical length of the connection line 600c refers to the phase shift that an electromagnetic wave experiences as it propagates along the connection line 600c. The electrical length may be expressed in radians or degrees relative to the operating wavelength. The total capacitance of the capacitors CA connected to the connection line 600c by the switches SW may adjust the electrical length of the connection line 600c.

Accordingly, the impedance characteristic of the impendence inside the chamber (210 of FIG. 1) may change to control the harmonics of the very high frequency among the frequencies of the RF power.

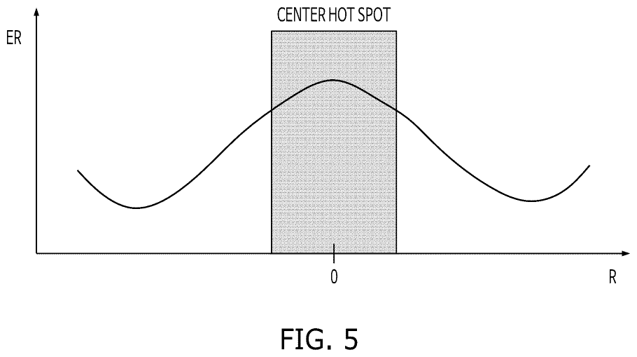

FIG. 5 is a graph illustrating an etching rate for the substrate in the chamber. The horizontal axis may refer to a radial location R of the substrate and the vertical axis may refer to an etching rate (ER: Etch Rate).

Referring to FIG. 5, in a typical plasma process, the etching rate may be higher in the center region of the substrate compared to in the edge region. The etching rate may decrease from the center toward the periphery of the substrate. Increasing in the etching rate toward the center of the substrate may be referred to the center hot spot phenomenon, and the center hot spot phenomenon is indicated by shading on the graph.

The center hot spot phenomenon may be intensified as the RF power increases. Various process problems such as punching, NOP (not open), crater, and clogging may occur due to the center hot spot phenomenon. The punching or NOP may be a problem in which a film is unintentionally pierced or a hole is not opened during the etching by plasma, and crater or clogging may be a problem in which the surface is separated or the hole inlet is closed due to the process gas control for suppressing the center hot spot phenomenon.

The cause of the center hot spot phenomenon is not specifically known. The harmonic components may increase the plasma density at the center of the substrate. Therefore, the increased plasma density may contribute to the increase in the etching rate at the center of the substrate.

For reference, in the case of a conventional substrate processing apparatus, the center hot spot phenomenon may be resolved by controlling the amount of process gas according to the position in the chamber, or by changing the shape of an upper electrode. However, the method of controlling the amount of process gas may cause control problems such as the crater and clogging problems described above. The method of changing the shape of the upper electrode may be inconvenient because the shape may be changed each time according to all process conditions. There is a problem that the upper electrode may experience a time-dependent change due to etching, and the compensation and prediction of the time-dependent change may be unattainable.

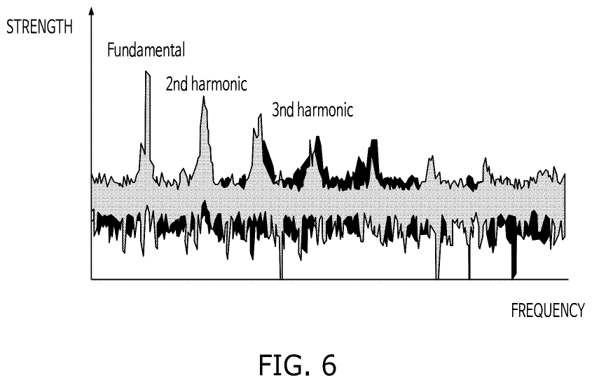

FIG. 6 is a graph illustrating components of a fundamental frequency and a harmonic of a very high frequency among the frequencies of an RF power on an RF transmission line. The horizontal axis refers to the frequency of the very high frequency and the vertical axis refers to the intensity of the very high frequency.

Referring to FIG. 1 and FIG. 6, in general, when the RF power is applied to the chamber 210, part of the harmonics among the frequencies of the RF power may be transmitted to the chamber 210, or the harmonics of the very high frequency may be generated due to the nonlinear characteristic of the RF power of the very high frequency and the plasma. The harmonics may cause a non-uniform distribution of the plasma in the chamber 210.

The graph of FIG. 6 illustrates that the harmonics of the very high frequency are detected in an RF bias transmission line 300, for example, an RF bias transmission line 300 implemented as an RF load. Peak parts may correspond to a fundamental frequency, a second harmonic, and a third harmonic of the very high frequency, respectively. For reference, the fundamental frequency may correspond to the first harmonic.

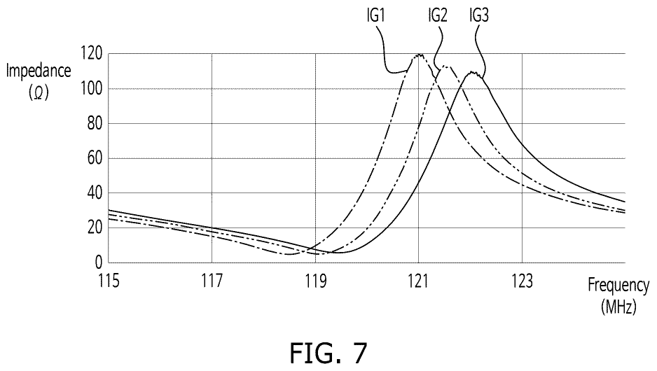

FIG. 7 is a graph illustrating the change of the impedance characteristic in the chamber in the substrate processing apparatus of FIG. 1. The horizontal axis may refer to the frequency of the very high frequency, and the vertical axis may refer to the impedance in the chamber. For example, the impedance characteristic in the chamber may correspond to a chamber impedance which reflects plasma impedance, transmission line effects, chamber walls, or electrodes. The chamber impedance may be measured using network analyzers (i.e., impedance analyzers), vector network analyzers using S-parameters, or Voltage Standing Wave Ratio (VSWR) sensors. When the RF power is not supplied, the plasma impedance may be omitted from the chamber impedance.

Referring to FIG. 1 and FIG. 7, a first graph IG1, a second graph IG2, and a third graph IG3) may indicate how the impedance characteristic in the chamber changes in a specific frequency band of the very high frequency according to the electrical length of a resonator 700 related to a driven element. The first graph IG1 may indicate the impedance characteristic when the resonator 700 has a first electrical length, the second graph IG2 may indicate the impedance characteristic when the resonator 700 has a second electrical length, and the third graph IG3 may indicate the impedance characteristic when the resonator 700 has a third electrical length. The first electrical length may be greater than the second and third electrical lengths. The second electrical length may be smaller than the first electrical length and greater than the third electrical length. The third electrical length may be smaller than the first and second electrical lengths.

In the first graph IG1, the second graph IG2, and the third graph IG3, the impendence characteristic in the chamber in the specific frequency band of the very high frequency may vary according to the electrical lengths of the resonator 700.

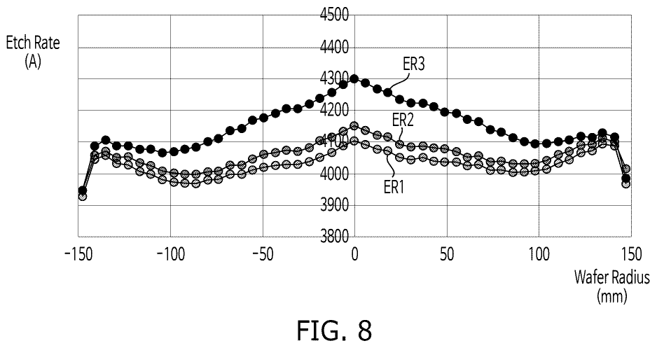

FIG. 8 is a graph illustrating a change of an etching rate at a center in a chamber in the substrate processing apparatus of FIG. 1. The horizontal axis refers to a radial position R of the substrate, and the vertical axis refers to an etching rate ER of the substrate.

Referring to FIG. 1 and FIG. 8, a first etching rate graph ER1, a second etching rate graph ER2, and a third etching rate graph ER3 indicate how the etching rate of a substrate W changes according to the electrical length of a resonator 700 related to a driven element. The first etching rate graph ER1 may indicate the etching rate of the substrate W when the resonator 700 has a first electrical length, the second etching rate graph ER2 may indicate the etching rate of the substrate W when the resonator 700 has a second electrical length, and the third etching rate graph ER3 may indicate the etching rate of the substrate W when the resonator 700 has a third electrical length. In this case, the first electrical length may be greater than the second and third electrical lengths. The second electrical length may be smaller than the first electrical length and greater than the third electrical length. The third electrical length may be smaller than the first and second electrical lengths.

In the first etching rate graph ER1, the second etching rate graph ER2, and the third etching rate graph ER3, as the electrical length of the resonator 700 increases, the etching rate at the center portion of the substrate W may decrease, and the etching rate of the outermost edge portion of the substrate W may increase.

The substrate processing apparatus 10 of embodiments of the present disclosure may effectively ease or remove the center hot spot phenomenon by the resonance frequency control through the resonator 700 related to the resonance control unit 400 and the driven element. The substrate process apparatus 10 may control the etching rate according to the position of the substrate W to be uniform.

FIG. 9 is a block diagram illustrating internal components of a resonance control unit according to embodiments of the present disclosure. Referring to FIG. 1 and FIG. 9, a resonance control unit 400 may include a resonator controller 410, a response analyzer 420, and an impulse generator 430.

The resonator controller 410 may be a signal processing device such as a Field-Programmable Gate Array (FPGA) and a Digital Signal Processor (DSP). The resonator controller 410 may be implemented as a device such as a microcontroller and a Programmable Logic Controller (PLC). However, the present disclosure is not limited thereto. The response analyzer 420 may include an Analog-to-Digital Converter (ADC) and may be implemented as a device such as an impedance analyzer and a Vector Network Analyzer (VNA), but the present disclosure is not limited thereto. The impulse generator 430 may be implemented as a high-speed pulse generator or an RF pulse generator, but the present disclosure is not limited thereto.

According to embodiments, the resonator controller 410 may control the harmonics for the very high frequency among the frequencies of the RF power by controlling the resonance frequency of the resonator 700 related to the driven element of the substrate processing apparatus 10. According to embodiments, the resonator controller 410 may transmit a signal that controls the electrical length or the electrical characteristic of the resonator 700 of the driven element to the resonator 700.

According to embodiments, the response analyzer 420 may detect a signal applied to the substrate support 222 and analyze a resonance impedance in the chamber 210. For example, when the substrate processing apparatus 10 is in a turn-off mode, the impulse generator 430 may transmit an impulse to the RF bias transmission line 300. The response analyzer 420 may detect the impulse response from an inlet 210-IL of the chamber 210 and analyze the resonance impedance of the chamber 210 based on the impulse response. The RF bias transmission line 300 may be inserted into the inside of the chamber 210 through the inlet 210-IL. The resonator controller 410 may control the electrical length or electrical characteristic of the resonator 700 based on the analyzed resonance impedance.

According to embodiments, when the substrate processing apparatus 10 is in a turn-on mode, the response analyzer 420 may detect an RF power from the inlet of the chamber of the RF bias transmission line 300, and analyze the resonance impedance in the chamber 210 based on the detected RF power.

The internal components of the resonance control unit 400 in FIG. 9 are only exemplary, but other components than the described internal components may be added or omitted in other embodiments of the present disclosure. Although the internal components of the resonance control unit 400 in FIG. 9 are functionally separated, it may not imply that the internal components are necessarily physically distinct.

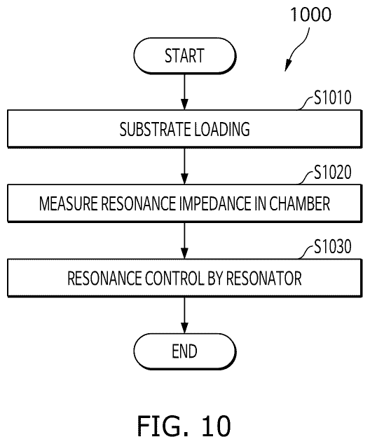

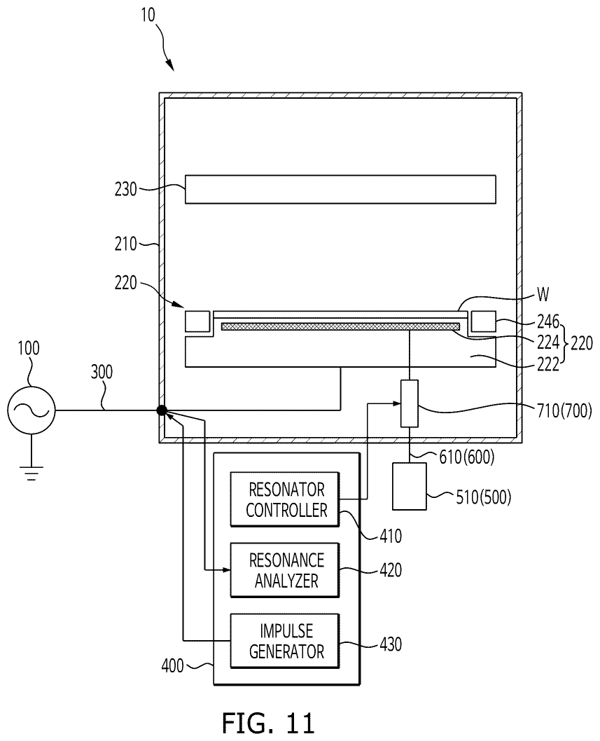

FIG. 10 and FIG. 11 are views illustrated to explain a substrate processing method according to embodiments of the present disclosure.

Referring to FIG. 10 and FIG. 11, a substrate processing method 1000 may be initiated by loading a substrate W on a substrate support 222 in step S1010. A resonance control unit 400 may measure a resonance impedance of a chamber 210 in step S1020. When the RF bias is not applied to the substrate support 222 (e.g., in a turn-off mode, where the RF power source is off and no plasma is generated), the impulse generator 430 may apply an impulse to the chamber 210 through the RF bias transmission line 300 connected to the substrate support 222. A response analyzer 420 may receive an impulse response to the impulse applied to the chamber 210 and analyze the resonance impedance of the chamber 210 based on the received impulse response. When the RF bias is applied to the substrate support 222 (e.g., in a turn-on mode, where RF power is supplied and plasma is generated), the response analyzer 420 may detect the RF bias applied to the substrate support 222 and analyze the resonance impedance of the chamber 210. Impedance measurements in both the turn-off mode and the turn-on mode are useful to distinguish between the intrinsic chamber impedance (e.g., structural, non-plasma elements) and plasma-induced impedance. This allows the system to establish a baseline for comparison and accurately adjust the resonance frequency depending on whether plasma is present.

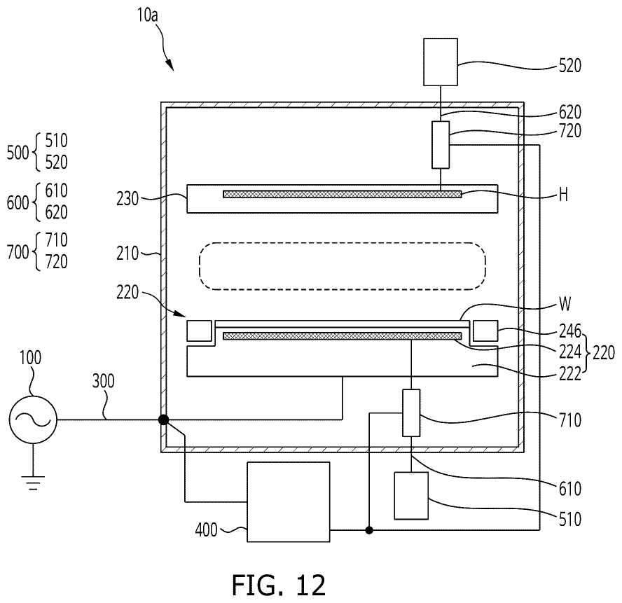

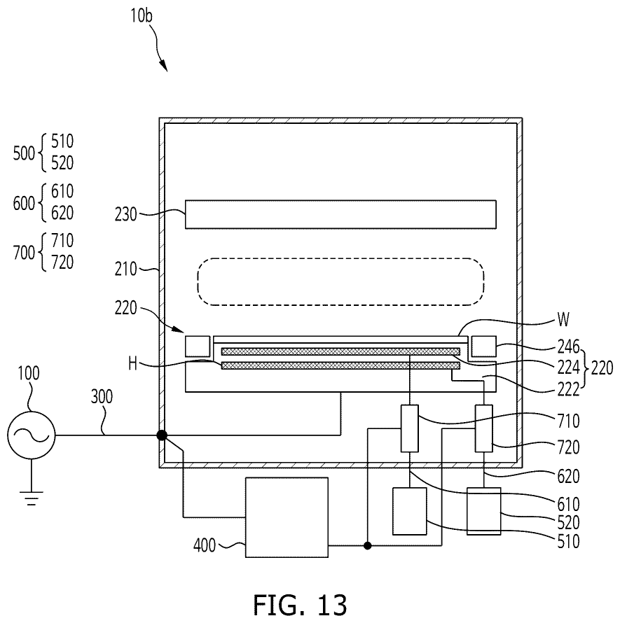

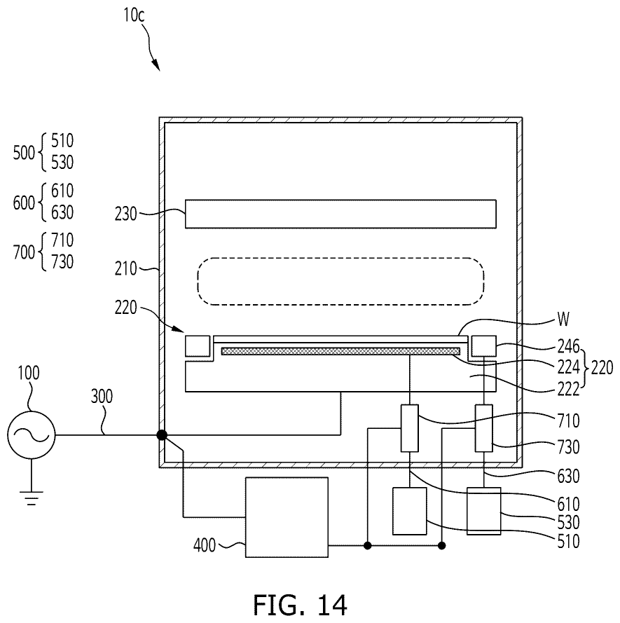

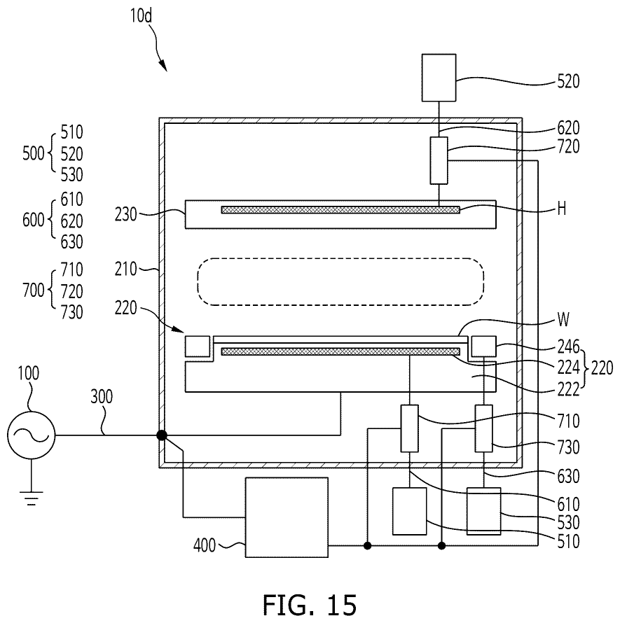

Based on the measured resonance impedance, the resonance frequency for the resonator 700 related to the driven element disposed inside the chamber 210 may be controlled in step S1030. The connection line on which the resonator is disposed may have a different path from the RF bias transmission line 300. For example, the resonator controller 410 may control the resonance frequency of at least one of the first resonator 710 related to the adsorption electrode 224, the second resonator (e.g., 720 of FIG. 12, FIG. 13, and FIG. 15) related to a heater, and the third resonator (e.g., 730 of FIG. 14 and FIG. 15) related to the edge ring 246. The driven element may include the adsorption electrode 224, the edge ring 246, and the heater (e.g., H of FIG. 13 to FIG. 15), but the present disclosure is not limited thereto. For example, the driven element may be driven by receiving a driving signal from the driving source 500 and include components in the substrate processing apparatus 10 where the driving signal forms an electrical field in the chamber 210 or changes an impedance to cause a change in the electrical characteristic in the chamber 210.

FIG. 12 is a view illustrated to explain a substrate processing apparatus 10a according to embodiments of the present disclosure. The substrate processing apparatus 10a described with reference to FIG. 12 may be substantially the same as the substrate process apparatus 10 described referring to FIG. 1 to FIG. 11 except having a heater H and a second resonator 720.

According to embodiments, the driven element may include the heater H that discharges heat when power is applied. The driving source 500 may include a heater power source 520 that applies a power to the heater H. According to embodiments, the heater H may be disposed inside the shower head 230.

The heater power source 520 may be electrically connected to the heater H through a second connection line 620. The second resonator 720 may be disposed on the second connection line 620. The resonance control unit 400 may control the resonance frequency of the second resonator 720. The resonance control unit 400 may change the resonance in a specific frequency band by controlling the second resonator 720, thereby adjusting the impendence in a specific frequency band in the chamber 210.

The resonance control unit 400 may selectively control the first resonator 710 and the second resonator 720. The resonance control unit 400 may simultaneously control the first resonator 710 and the second resonator 720.

According to embodiments, the second connection line 620 itself may function as the second resonator 720. The second connection line 620 may have a structure that changes the resonance in a specific frequency band by the resonance control unit 400.

FIG. 13 is a view illustrated to explain a substrate processing apparatus 10b according to embodiments of the present disclosure. The substrate processing apparatus 10b described referring to FIG. 13 may be substantially the same as the substrate processing apparatus 10a described referring to FIG. 12 except that the heater H is disposed in a lower portion in the chamber 210. Referring to FIG. 12, the heater H may be disposed in the substrate support 222.

FIG. 14 is a view illustrated to explain a substrate processing apparatus 10c according to embodiments of the present disclosure. The substrate processing apparatus 10c described referring to FIG. 14 may be substantially the same as the substrate processing apparatus 10 described referring to FIG. 1 to FIG. 11 except having a third resonator 730 related to the edge ring 246.

According to embodiments, the driven element may include the edge ring 246 disposed on the substrate support 222. The driving source 500 may include an edge ring control signal source 530 that applies an impedance control signal to the edge ring 246. The edge ring control signal source 530 may be electrically connected to the edge ring 246 through a third connection line 630. According to embodiments, the edge ring control signal source 530 and the edge ring 246 may be indirectly connected. The third connection line 630 may be connected to the edge ring control signal source 530. According to embodiments, the impedance control signal from the edge ring control signal source 530 may be applied to a region adjacent to the edge ring 246 via the third connection line 630. A variable impedance element, such as the third resonator 730, may be disposed on the third connection line 630. The third resonator 730 may adjust the impedance of the region adjacent to the edge ring 246 in a specific frequency band, without directly changing the intrinsic impedance of the edge ring 246 itself. This enables tuning of the electrical environment around the edge ring 246, which in turn affects the plasma distribution and the impedance characteristics in the chamber 210. Therefore, the characteristic impedance of an area adjacent to the edge ring 246 may be controlled. The third resonator 730 may be placed on the third connection line 630. In this case, the resonance control unit 400 may control the resonance frequency of the third resonator 730. The resonance control unit 400 may change the resonance in a specific frequency band by controlling the third resonator 730 to adjust the impedance in a specific frequency band in the chamber 210.

The resonance control unit 400 may selectively control the first resonator 710 and the third resonator 730. The resonance control unit 400 may simultaneously control the first resonator 710 and the third resonator 730.

According to embodiments, the third connection line 630 itself may function as the third resonator 730. The third connection line 630 may have a structure that changes the resonance in a specific frequency band by the resonance control unit 400.

FIG. 15 is a view illustrated to explain a substrate processing apparatus 10d according to embodiments of the present disclosure. The substrate processing apparatus 10d described referring to FIG. 15 may be substantially the same as the substrate processing apparatus 10c described referring to FIG. 14 except having a heater H and a second resonator 720.

The resonance control unit 400 may selectively control at least one or more of the first resonator 710, the second resonator 720, and the third resonator 730. The resonance control unit 400 may simultaneously control the first resonator 710, the second resonator 720 and the third resonator 730.

The substrate processing apparatus 10d of FIG. 15 is illustrated as having the heater H disposed in the upper portion in the chamber 210, i.e., inside the shower head 230, but the present disclosure is not limited thereto. The heater H may be disposed in the substrate support 222 as in the substrate processing apparatus 10b described referring to FIG. 13.

While the present disclosure has been described with reference to exemplary embodiments thereof, but it is to be understood that the present disclosure is not limited to the exemplary embodiments. It will be apparent to those skilled in the art that various modifications and changes may be made within the scope of the appended claims and their equivalents.

What is claimed is:

1. A substrate processing apparatus, comprising:
a chamber in which a substrate processing process is performed;
a substrate support disposed in the chamber and configured to support a substrate;
a radio frequency (RF) power source configured to provide an RF power to the substrate support;
an RF power transmission line configured to electrically connect the substrate support to the RF power source;
a driven element disposed in the chamber;
a driving source configured to provide a driving signal to the driven element;
a connection line configured to electrically connect the driven element to the driving source;
a resonator disposed on the connection line; and
a resonance control circuit including a resonator controller that controls a resonance frequency of the resonator,
wherein the RF power transmission line and the connection line have different paths.

2. The substrate processing apparatus of claim 1,
wherein the resonator comprises:
a casing configured to surround at least a part of the connection line, wherein the casing includes a first end surface, a second end surface, and a side surface connecting the first end surface to the second end surface, wherein the connection line penetrates through the first end surface and the second end surface, and wherein the first end surface is closer to the driving source than the second end surface; and
a dielectric configured to partially fill a space between the connection line and the casing and to be movably attached to the connection line.

3. The substrate processing apparatus of claim 2,
wherein the resonator controller is configured to control the resonance frequency of the resonator by adjusting a position of the dielectric along a longitudinal direction of the connection line relative to the first end surface.

4. The substrate processing apparatus of claim 1,
wherein the resonator comprises:
a casing configured to surround at least a part of the connection line; and
a dielectric configured to fill a space between the connection line and the casing, and
wherein the casing includes an inlet through which the dielectric flows in and an outlet through which the dielectric flows out.

5. The substrate processing apparatus of claim 4,
wherein the resonator controller is configured to control the resonance frequency of the resonator by adjusting inflow and outflow of the dielectric.

6. The substrate processing apparatus of claim 1,
wherein the resonator comprises:
a plurality of capacitors connected in parallel on the connection line; and
a plurality of switches disposed between the connection line and the plurality of capacitors, respectively.

7. The substrate processing apparatus of claim 6,
wherein the resonator controller is configured to control the resonance frequency of the resonator by controlling operations of the plurality of switches.

8. The substrate processing apparatus of claim 1,
wherein the driven element includes an adsorption electrode disposed in the substrate support, and
wherein the driving source includes an adsorption electrode power source that applies a power to the adsorption electrode.

9. The substrate processing apparatus of claim 1,
wherein the driven element includes a heater configured to discharge heat when a power is applied, and
wherein the driving source includes a heater power source that applies a power to the heater.

10. The substrate processing apparatus of claim 9, further comprising:
a shower head disposed in the chamber and facing the substrate support,
wherein the heater is disposed in the shower head.

11. The substrate processing apparatus of claim 9, wherein the heater is disposed in the substrate support.

12. The substrate processing apparatus of claim 1,
wherein the driven element includes an edge ring in a ring shape disposed on the substrate support, and
wherein the driving source includes an edge ring control signal source that applies an impedance control signal to a region adjacent to the edge ring via the connection line.

13. The substrate processing apparatus of claim 1,
wherein the resonance control circuit further comprises:
an impulse generator configured to apply an impulse to the chamber through the RF power transmission line connected to the substrate support; and
a response analyzer configured to receive an impulse response for the impulse applied to the chamber, and analyze a resonance impedance of the chamber based on the received impulse response.

14. The substrate processing apparatus of claim 13,
wherein the resonator controller is configured to control the resonance frequency of the resonator based on the analyzed resonance impedance.

15. The substrate processing apparatus of claim 1,
wherein the resonance control circuit further comprises:
a response analyzer configured to detect the RF power applied to the substrate support, and analyze a resonance impedance in the chamber, and
wherein the resonator controller is configured to control the resonance frequency of the resonator based on the analyzed resonance impedance.

16. A substrate processing apparatus, comprising:
a chamber in which a substrate processing process is performed;
a substrate support disposed in the chamber, and configured to support a substrate;
an adsorption electrode disposed in the substrate support;
an adsorption electrode power source configured to apply a power to the adsorption electrode;
a first connection line configured to electrically connect the adsorption electrode to the adsorption electrode power source;
a first resonator disposed on the first connection line;
an edge ring in a ring shape disposed on the substrate support;
an edge ring control signal source configured to apply an impedance control signal to a region adjacent to the edge ring via a second connection line;
a second resonator disposed on the second connection line; and
a resonance control circuit configured to control a resonance frequency of at least one of the first resonator and the second resonator.

17. The substrate processing apparatus of claim 16,
wherein the resonance control circuit is configured to:
apply an impulse to the chamber through an RF power transmission line connected to the substrate support without applying an RF power to the substrate support through the RF power transmission line,
receive an impulse response for the impulse applied to the chamber, and
analyze a resonance impedance of the chamber based on the received impulse response.

18. The substrate processing apparatus of claim 16,
wherein the resonance control circuit is configured to detect an RF power applied to the substrate support, and analyze a resonance impedance in the chamber.

19. The substrate processing apparatus of claim 16, further comprising:
an RF power source configured to provide an RF power to the substrate support; and
an RF power transmission line configured to electrically connect the substrate support to the RF power source,
wherein the RF power transmission line, and the first connection line, and the second connection line have different paths.

20. A substrate processing apparatus, comprising:
a chamber in which a substrate processing process is performed;
a substrate support disposed in the chamber and configured to support a substrate;
a shower head disposed in the chamber to face the substrate support;
an RF power source configured to provide an RF power to the substrate support;
an RF power transmission line configured to electrically connect the substrate support to the RF power source;
an adsorption electrode disposed in the substrate support;
an adsorption electrode power source configured to apply a power to the adsorption electrode;
a first connection line configured to electrically connect the adsorption electrode to the adsorption electrode power source;
a first resonator disposed on the first connection line;
a heater disposed in the shower head, and configured to discharge heat when a heater power is applied;
a heater power source configured to apply the heater power to the heater;
a second connection line configured to electrically connect the heater to the heater power source;
a second resonator disposed on the second connection line;
an edge ring in a ring shape disposed on the substrate support;
an edge ring control signal source configured to apply an impedance control signal to a region adjacent to the edge ring via a third connection line;
a third resonator disposed on the third connection line; and
a resonance control circuit including a resonator controller configured to control a resonance frequency of at least one of the first resonator, the second resonator, and the third resonator,
wherein the RF power transmission line, the first connection line, the second connection line, and the third connection line have different paths.
